(19) United States
(12) Patent Application Publication
(10) Pub. No.: US 2023/0307595 A1
(43) Pub. Date: Sep. 28, 2023

(54) DISPLAY DEVICE AND METHOD FOR MANUFACTURING DISPLAY DEVICE

(71) Applicant: KYOCERA Corporation, Kyoto-shi, Kyoto (JP)

(72) Inventor: Masaya TAMAKI, Yokohama-shi, Kanagawa (JP)

(21) Appl. No.: 18/023,705

(22) PCT Filed: Aug. 2, 2021
(86) PCT No.: PCT/JP2021/028586

§ 371 Date: Feb. 27, 2023

(30) Foreign Application Priority Data
Aug. 31, 2020 (JP) 2020-146129

(51) Int. Cl. H01L 33/60; H01L 25/16; H01L 33/56

(52) U.S. Cl. CPC H01L 33/60; H01L 25/167; H01L 33/56; H01L 2933/0058; H01L 2933/005

(57) ABSTRACT

A display device includes a first substrate, a second substrate, a light emitter, a first transparent member, and a second transparent member. The second substrate is on the first substrate. The second substrate includes a through-hole extending through the second substrate in a direction in which the second substrate is placed on the first substrate. The light emitter includes an upper surface and a side surface. The light emitter is mounted on a portion of the first substrate exposed by the through-hole. The first transparent member is in the through-hole. The first transparent member seals at least the side surface of the light emitter. The second transparent member is on the first transparent member in the through-hole. The second transparent member has a lower refractive index and a greater thickness than the first transparent member.

### TECHNICAL FIELD

The present disclosure relates to a display device including self-luminous light emitters such as light-emitting diodes (LEDs), and a method for manufacturing the display device.

### BACKGROUND OF INVENTION

A known display device is described in, for example, Patent Literature 1.

### CITATION LIST

### Patent Literature

Patent Literature 1: Japanese Unexamined Utility Model Application Publication No. 6-54081

### SUMMARY

In an aspect of the present disclosure, a display device includes a first substrate, a second substrate, a light emitter, a first transparent member, and a second transparent member. The second substrate is on the first substrate. The second substrate includes a through-hole extending through the second substrate in a direction in which the second substrate is placed on the first substrate. The light emitter is mounted on a portion of the first substrate exposed by the through-hole. The light emitter includes an upper surface, a side surface, and a lower surface. The first transparent member is in the through-hole. The first transparent member seals at least the side surface of the light emitter. The second transparent member is on the first transparent member in the through-hole. The second transparent member has a lower refractive index and a greater thickness than the first transparent member.

In an aspect of the present disclosure, a method for manufacturing a display device includes preparing a first substrate including a mounting surface. The mounting surface includes a portion on which a light emitter is mountable. The method also includes preparing a second substrate including a through-hole, and mounting a light emitter on the portion of the first substrate. The light emitter includes an upper surface, a side surface, and a lower surface. The method also includes applying a first transparent resin to the mounting surface and to at least the side surface of the light emitter, placing the second substrate on the mounting surface of the first substrate to position the light emitter in the through-hole, and curing the first transparent resin to form a first transparent member in the through-hole and between the first substrate and the second substrate. The first transparent member fixes the first substrate and the second substrate to each other and seals the light emitter. The method also includes filling the through-hole with a second transparent resin. The second transparent resin has a lower refractive index than the first transparent resin. The method also includes curing the second transparent resin to form a second transparent member thicker than the first transparent member.

### BRIEF DESCRIPTION OF THE DRAWINGS

The objects, features, and advantages of the present disclosure will become more apparent from the following detailed description and the drawings.

FIG. 1 is a schematic plan view of a display device according to an embodiment of the present disclosure.

FIG. 2A is a cross-sectional view taken along line A1-A2 in FIG. 1.

FIG. 2B is a cross-sectional view of a display device according to another embodiment of the present disclosure corresponding to FIG. 2A.

FIG. 3 is a schematic cross-sectional view of a display device according to a variation of the display device in FIG. 1.

FIG. 4 is a schematic cross-sectional view of a display device according to a variation of the display device in FIG. 1.

FIG. 5 is a schematic cross-sectional view of a display device according to a variation of the display device in FIG. 1.

FIG. 6 is a schematic cross-sectional view of a display device according to a variation of the display device in FIG. 1.

FIG. 7 is a schematic cross-sectional view of a display device according to a variation of the display device in FIG. 1.

FIG. 8 is a schematic cross-sectional view of a display device according to a variation of the display device in FIG. 2A.

FIG. 9A is a schematic cross-sectional view of a display device according to a variation of the display device in FIG. 8.

FIG. 9B is a schematic cross-sectional view of a display device according to a variation of the display device in FIG. 8.

FIG. 10A is a schematic cross-sectional view of a display device according to a variation of the display device in FIG. 8.

FIG. 10B is a schematic cross-sectional view of a display device according to a variation of the display device in FIG. 8.

FIG. 10C is a schematic cross-sectional view of a display device according to a variation of the display device in FIG. 8.

FIG. 10D is a schematic cross-sectional view of a display device according to a variation of the display device in FIG. 8.

FIG. 11A is a schematic cross-sectional view of a display device according to a variation of the display device in FIG. 8.

FIG. 11B is a schematic cross-sectional view of a display device according to a variation of the display device in FIG. 8.

FIG. 11C is a schematic cross-sectional view of a display device according to a variation of the display device in FIG. 8.

FIG. 11D is a schematic cross-sectional view of a display device according to a variation of the display device in FIG. 8.

FIG. 12 is a flowchart of a method for manufacturing the display device according to an embodiment of the present disclosure.

### DESCRIPTION OF EMBODIMENTS

The structure that forms the basis of a display device according to one or more embodiments of the present disclosure will be described. A variety of display devices including multiple self-luminous light emitters such as light-emitting diodes (LEDs) have been developed. Patent Literature 1 describes a display device including a first plate on which multiple LEDs are arranged and a second plate including multiple through-holes corresponding to the LEDs. Each LED is sealed with a light-transmissive resin.

In the field of display devices, the definition and the light output efficiency are to be increased. To increase the definition and the light output efficiency of known display devices, the first plate and the second plate may be fixed to each other more securely, and light emitters may be sealed more tightly.

A display device according to one or more embodiments of the present disclosure will now be described with reference to the accompanying drawings. Each figure referred to below illustrates main components and other elements of the display device according to one or more embodiments. The display device according to one or more embodiments may include known components that are not illustrated, for example, circuit boards, wiring conductors, control ICs, and LSI circuits.

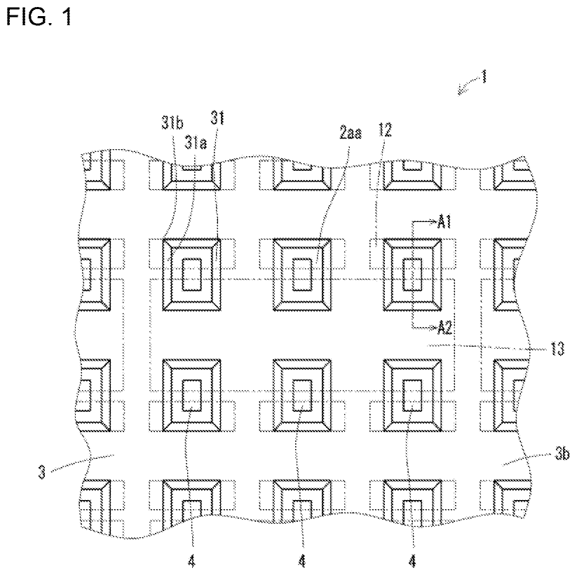

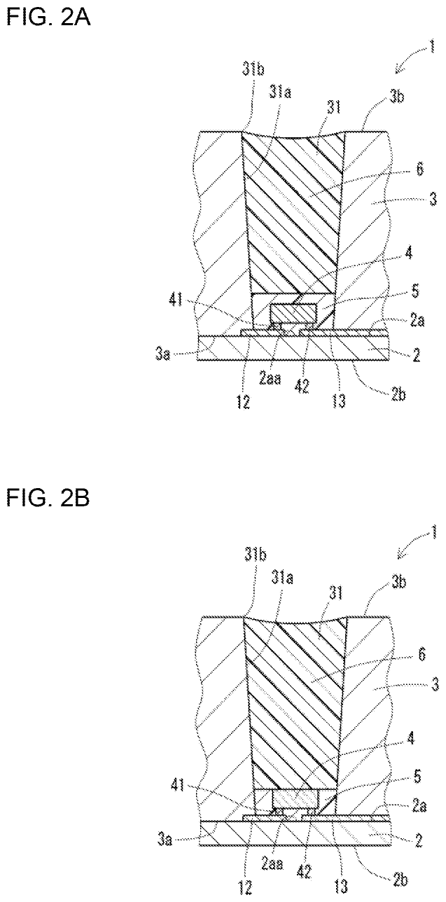

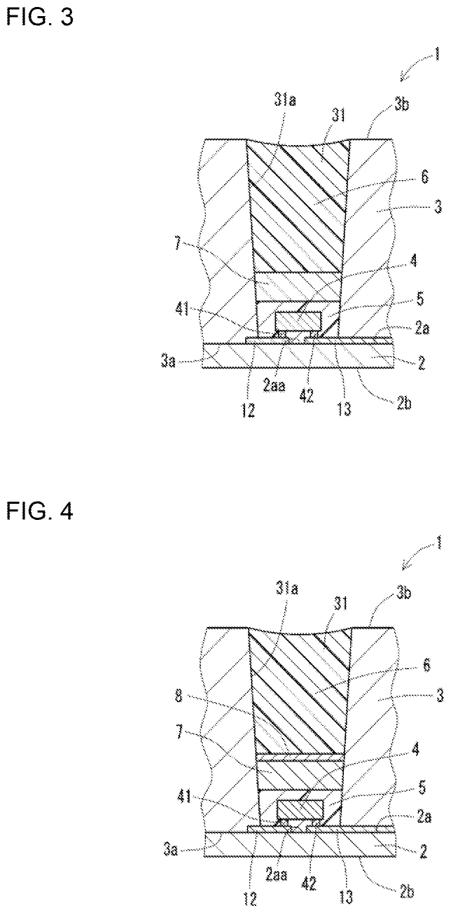

FIG. 1 is a schematic plan view of a display device according to an embodiment of the present disclosure. FIGS. 2A and 2B are each a cross-sectional view taken along line A1-A2 in FIG. 1. FIGS. 3 to 6 are each a schematic cross-sectional view of a display device according to a variation of the display device in FIG. 1. The cross-sectional views of FIGS. 3 to 6 correspond to the cross-sectional view of FIG. 2A.

In one or more embodiments of the present disclosure, the display device 1 includes a first plate 2 as a first substrate, a second plate 3 as a second substrate, light emitters 4, a first transparent member 5, and a second transparent member 6. The second plate 3 is on the first plate 2 and includes through-holes 31 extending through the second plate 3 in the direction in which the second plate 3 is placed on the first plate 2. The light emitters 4 are mounted on portions 2aa of the first plate 2 exposed by the through-holes 31. Each light emitter 4 includes an upper surface, a side surface, and a lower surface. The first transparent member 5 is in each through-hole 31 and seals at least the side surface of the light emitter 4. The second transparent member 6 is on the first transparent member 5 in each through-hole 31. The second transparent member 6 has a lower refractive index and a greater thickness than the first transparent member 5.

The above structure produces the advantageous effects described below. The display device 1 includes the second transparent member 6 located on the first transparent member 5 in each through-hole 31 in the second substrate 3. The second transparent member 6 has a lower refractive index and a greater thickness than the first transparent member 5. The second transparent member 6, which guides light effectively, allows efficient output of light radiated from each light emitter 4 outside. This structure also facilitates reflection of light radiated from each light emitter 4 on an inner peripheral surface 31a of the through-hole 31 while reducing total internal reflection at the interface between the first transparent member 5 and the second transparent member 6. This facilitates efficient output of light radiated from the light emitters 4 outside, and increases the directivity of light radiated outside through the through-holes 31. The first transparent member 5 and the second transparent member 6 hermetically seal each light emitter 4 and efficiently transfer heat from the light emitter 4 to the second substrate 3, which then dissipates the heat. This improves the device reliability.

A first substrate 2 and a second substrate 3 may each be, for example, a plate-like substrate, a block, a flexible sheet, or a three-dimensional structure with a curved surface, a surface with protrusions and recesses, or another non-flat surface. In the example described below, the first substrate 2 is the first plate 2, and the second substrate 3 is the second plate 3. The through-holes 31 also serve as cavities (recesses) accommodating the light emitters 4 and reflecting light radiated from the light emitters 4 with their inner peripheral surfaces 31a.

Each light emitter 4 has a shape defined by an upper surface, a side surface, and a lower surface. Examples of such shapes include a cube, a rectangular prism, a cylinder, an elliptic cylinder, a triangular prism, a polygonal prism, a cone, and a pyramid.

The first transparent member 5 seals at least the side surface of each light emitter 4. The upper surface of each light emitter 4 may be covered with the first transparent member 5 as illustrated in FIG. 2A, or may be exposed through the first transparent member 5 as illustrated in FIG. 2B. For example, the upper surface of each light emitter 4 may be exposed through the first transparent member 5, and a wavelength converter 7 may be located between the first transparent member 5 and the second transparent member 6. In this case, the wavelength converter 7 directly receives light radiated from the upper surface of the light emitter 4, and converts the wavelength efficiently.

Each light emitter 4 may have its lower surface connected horizontally by flip-chip connection. In this case, the lower surface of the light emitter 4 may be spaced from a first surface 2a of the first plate 2 and covered and sealed with the first transparent member 5. In some embodiments, each light emitter 4 may be connected vertically. More specifically, each light emitter 4 may include a terminal with a polarity on its lower surface, and the terminal may be connected to an electrode with a polarity on the first surface 2a of the first plate 2. In this case, the lower surface of the light emitter 4 may not be spaced from the first surface 2a of the first plate 2 and may not be sealed with the first transparent member 5.

In the present embodiment, the display device 1 includes the first plate 2, the second plate 3, the light emitters 4, the first transparent member 5, and the second transparent member 6.

The first plate 2 includes the first surface (first main surface) 2a. The first surface 2a also serves as a mounting surface on which the light emitters 4 are mounted. The first plate 2 may be, for example, triangular, square, rectangular, hexagonal, trapezoidal, circular, oval, or in any other shape as viewed in plan (in other words, as viewed in a direction perpendicular to the first surface 2a).

The first plate 2 is made of, for example, a glass material, a ceramic material, a resin material, a metal material, or a semiconductor material.

Examples of the glass material used for the first plate 2 include borosilicate glass, crystallized glass, quartz, and soda glass. Examples of the ceramic material used for the first plate 2 include alumina (Al₂O₃), aluminum nitride (AlN), silicon nitride (Si₃N₄), zirconia (ZrO₂), and silicon carbide (SiC). Examples of the resin material used for the first plate 2 include an epoxy resin, a polyimide resin, and a polyamide resin. Examples of the metal material used for the first plate 2 include aluminum (Al), titanium (Ti), beryllium (Be), magnesium (Mg) (specifically, high-purity magnesium with a Mg content of 99.95% or higher), zinc (Zn), tin (Sn), copper (Cu), iron (Fe), chromium (Cr), nickel (Ni), and silver (Ag). The metal material used for the first plate 2 may be an alloy material. Examples of the alloy material used for the first plate 2 include an iron alloy mainly containing iron (a Fe—Ni alloy, a Fe—Ni—Co (cobalt) alloy, a Fe—Cr alloy, or a Fe—Cr—Ni alloy), duralumin, which is an aluminum alloy mainly containing aluminum (an Al—Cu alloy, an Al—Cu—Mg alloy, or an Mg—Zn—Mg—Cu alloy), a magnesium alloy mainly containing magnesium (a Mg—Al alloy, a Mg—Zn alloy, or a Mg—Al—Zn alloy), titanium boride, and a Cu—Zn alloy. Examples of the semiconductor material used for the first plate 2 include silicon (Si), germanium (Ge), and gallium arsenide (GaAs).

The first plate 2 may include a single layer of, for example, the glass material, the ceramic material, the resin material, the metal material, or the semiconductor material described above, or may be a stack of multiple layers of any of these materials. For the first plate 2 being a stack of multiple layers, the layers may be made of the same or different materials.

As illustrated in, for example, FIG. 2A, the second plate 3 is located on the first surface 2a of the first plate 2. The second plate 3 is a plate or a block. The second plate 3 includes a second surface 3a facing the first surface 2a of the first plate 2, and a third surface 3b opposite to the second surface 3a. The third surface 3b of the second plate 3 is the display surface of the display device 1 for emitting image light. The second plate 3 may be, for example, triangular, square, rectangular, hexagonal, trapezoidal, circular, oval, or in any other shape as viewed in plan. The first plate 2 and the second plate 3 may have the same shape as viewed in plan.

The second plate 3 includes the through-holes 31 extending through the second plate 3 from the second surface 3a to the third surface 3b. The through-holes 31 expose portions (or element-mounting portions) 2aa of the first surface 2a. Each through-hole 31 may have a section parallel to the third surface 3b of the second plate 3 being, for example, square, rectangular, circular, oval, or in any other shape. Each through-hole 31 may have a section parallel to the third surface 3b being gradually smaller in the direction from the third surface 3b toward the second surface 3a. Each through-hole 31 includes an opening 31b in the third surface 3b. In the display device 1, each opening 31b may have an outer edge surrounding the outer edge of the corresponding element-mounting portion 2aa as viewed in plan. In other words, each through-hole 31 may be larger at the upper opening 31b than at the lower opening. This allows efficient output of light emitted from the light emitters 4 outside.

The second plate 3 is made of, for example, a glass material, a ceramic material, a resin material, a metal material, or a semiconductor material.

Examples of the glass material used for the second plate 3 include borosilicate glass, crystallized glass, quartz, and soda glass. Examples of the ceramic material used for the second plate 3 include alumina, aluminum nitride, silicon nitride, zirconia, and silicon carbide. Examples of the resin material used for the second plate 3 include an epoxy resin, a polyimide resin, and a polyamide resin. Examples of the metal material used for the second plate 3 include aluminum, titanium, beryllium, magnesium (specifically, high-purity magnesium with a Mg content of 99.95% or higher), zinc, tin, copper, iron, chromium, nickel, and silver. The metal material used for the second plate 3 may be an alloy material. Examples of the alloy material used for the second plate 3 include an iron alloy mainly containing iron (a Fe—Ni alloy, a Fe—Ni—Co alloy, a Fe—Cr alloy, or a Fe—Cr—Ni alloy), duralumin, which is an aluminum alloy mainly containing aluminum (an Al—Cu alloy, an Al—Cu—Mg alloy, or an Al—Zn—Mg—Cu alloy), a magnesium alloy mainly containing magnesium (a Mg—Al alloy, a Mg—Zn alloy, or a Mg—Al—Zn alloy), titanium boride, and a Cu—Zn alloy. Examples of the semiconductor material used for the second plate 3 include silicon, germanium, and gallium arsenide.

The second plate 3 may include a single layer of the above metal material, or may be a stack of multiple layers of the above metal material. For the second plate 3 being a stack of multiple layers, the layers may be made of the same or different materials. The through-holes 31 may be formed by, for example, punching, electroforming (plating), cutting, or laser beam machining. For the second plate 3 made of a metal material, the through-holes 31 may be formed by, for example, punching or electroforming. For the second plate 3 made of a semiconductor material, the through-holes 31 may be formed by, for example, photolithography including dry etching.

For the second plate 3 made of a metal material or a semiconductor material, an insulator or an insulating layer made of an electrically insulating material may be between the first surface 2a of the first plate 2 and the second surface 3a of the second plate 3. This reduces short-circuiting between electrodes, wiring conductors, or other components on the first surface 2a through the second plate 3. Examples of the electrically insulating material used for the insulator or the insulating layer include silicon oxide and silicon nitride.

The light emitters 4 are mounted on the element-mounting portions 2aa of the first plate 2 exposed by the through-holes 31. The light emitters 4 are self-luminous. Examples of the self-luminous light emitters include LEDs, organic LEDs (OLEDs), and semiconductor laser diodes (LDs). In the present embodiment, the display device 1 includes LEDs as the light emitters 4. Each LED includes two terminals, or specifically, an anode terminal 41 and a cathode terminal 42. The light emitters 4 may be micro-LEDs. Each micro-LED mounted on the element-mounting portion 2aa may be rectangular as viewed in plan with each side having a length of about 1 to 100 μm inclusive, or about 5 to 20 μm inclusive.

The display device 1 includes anode electrodes 12 and cathode electrodes 13. As illustrated in, for example, FIGS. 1, 2A, and 2B, the anode electrodes 12 and the cathode electrodes 13 are located on the first surface 2a of the first plate 2. The anode electrodes 12 and the cathode electrodes 13 may be located on the element-mounting portions 2aa of the first surface 2a. The anode terminals 41 of the light emitters 4 are electrically connected to the anode electrodes 12. The cathode terminals 42 of the light emitters 4 are electrically connected to the cathode electrodes 13.

The light emitters 4 may be connected to the anode electrodes 12 and the cathode electrodes 13 by flip-chip connection. The light emitters 4 may be electrically and mechanically connected to the anode electrodes 12 and the cathode electrodes 13 by flip-chip connection using conductive connectors, such as solder balls, metal bumps, a conductive adhesive, or an anisotropic conductive film (ACF). The light emitters 4 may be connected to the anode electrodes 12 and the cathode electrodes 13 with a method other than flip-chip connection. The light emitters 4 may be electrically connected to the anode electrodes 12 and the cathode electrodes 13 using conductive connectors such as bonding wires.

For the first plate 2 made of a metal material or a semiconductor material, an insulating layer of, for example, silicon oxide or silicon nitride may be located on at least the first surface 2a of the first plate 2, and the anode electrodes 12 and the cathode electrodes 13 may be located on the insulating layer. This reduces electrical short-circuiting between the anode terminals 41 and the cathode terminals 42 of the light emitters 4 electrically connected to the anode electrodes 12 and the cathode electrodes 13.

The anode electrodes 12 and the cathode electrodes 13 are connected to a drive circuit. The drive circuit controls, for example, the emission or non-emission state and the light intensity of each light emitter 4. The drive circuit may be located on, for example, the first main surface 2a of the first plate 2, or may be located on the second main surface 2b of the first plate 2. The drive circuit may be between multiple insulating layers of, for example, silicon oxide or silicon nitride located on the first main surface 2a or on the second main surface 2b.

The drive circuit includes, for example, a thin-film transistor (TFT) and a wiring conductor. The TFT may include a semiconductor film (or a channel) of, for example, amorphous silicon (a-Si) or low-temperature polycrystalline silicon (LTPS). The TFT may include three terminals, or specifically, a gate electrode, a source electrode, and a drain electrode. The TFT serves as a switching element that switches conduction and non-conduction between the source electrode and the drain electrode based on the voltage applied to the gate electrode. The drive circuit may be formed using a thin film formation method such as chemical vapor deposition (CVD).

The first transparent member 5 is between the first surface 2a of the first plate 2 and the second surface 3a of the second plate 3. The first transparent member 5 is located in each through-hole 31. As illustrated in, for example, FIG. 2A, the first transparent member 5 is located on the element-mounting portion 2aa of the first surface 2a in each through-hole 31. The first transparent member 5 fixes the first plate 2 and the second plate 3 to each other and seals each light emitter 4.

The first transparent member 5 may be made of a transparent resin adhesive. In this case, the first transparent member 5 fixes the first plate 2 and the second plate 3 to each other more securely. The first transparent member 5 made of a transparent resin adhesive may be an epoxy resin, which is common as a resin adhesive, or may be an adhesive transparent resin such as an acrylic resin, a polycarbonate resin, or a silicone resin.

As illustrated in, for example, FIG. 2A, the first transparent member 5 may have a non-uniform thickness. For example, the second plate 3 may be spaced away from the first plate 2, and the first transparent member 5 may extend between the first plate 2 and the second plate 3. The first transparent member 5, which also serves as a fixing member, can fix the first plate 2 and the second plate 3 to each other more securely by extending between the first plate 2 and the second plate 3.

The first transparent member 5 may include an extension extending between the first plate 2 and the second plate 3, and the extension may be thinner than the portion of the first transparent member 5 located in each through-hole 31. This reduces the likelihood that light radiated from the light emitters 4 enters the adjacent through-holes 31 through the extension. The portion of the first transparent member 5 located on the element-mounting portion 2aa in each through-hole 31 may have a thickness of, for example, about 2 to 15 μm inclusive. The extension of the first transparent member 5 extending between the first surface 2a and the second surface 3a may have a thickness of, for example, about 2 to 5 μm inclusive. The thickness herein may refer to the thickness in the direction orthogonal to the first surface 2a of the first plate 2.

The second plate 3 may be located on the first plate 2 with no space between them, and the first transparent member 5 may be located in each through-hole 31 alone. This prevents light radiated from the light emitters 4 from entering the adjacent through-holes 31.

The first transparent member 5 is made of, for example, a transparent resin (first transparent resin). The first transparent resin may be, for example, an ultraviolet curable resin, a thermosetting resin, or a two-part curable resin. Examples of the first transparent resin include a silicone resin and an epoxy resin. The first transparent member 5 may have a refractive index of, for example, about 1.4 to 1.9 inclusive.

The first transparent member 5 may include a body made of the first transparent resin and multiple light scattering particles dispersed in the body. The light scattering particles may have a higher refractive index than the body. The light scattering particles may be made of, for example, titanium dioxide (TiO₂) or ZrO₂. The light scattering particles scatter light received from outside. The light scattering particles reduce the likelihood that light enters the first transparent member 5 from outside and interferes with light emitted from each light emitter 4. The display device 1 can thus avoid lowering the image quality.

The second transparent member 6 is located in each through-hole 31 in the second plate 3. The second transparent member 6 is nearer the third surface 3b than the first transparent member 5. The second transparent member 6 may be in contact with the first transparent member 5. In some embodiments, the second transparent member 6 may be separated from the first transparent member 5 by another optical component. The second transparent member 6 is thicker than the first transparent member 5. As illustrated in, for example, FIG. 2A, the second transparent member 6 may be thicker than the portion of the first transparent member 5 located on the element-mounting portion 2aa in each through-hole 31. The second transparent member 6 may have a thickness greater than a half, or more specifically, greater than two-thirds, of the thickness of the second plate 3.

The second transparent member 6 is made of a transparent resin (second transparent resin). The second transparent resin may be, for example, an ultraviolet curable resin, a thermosetting resin, or a two-part curable resin. Examples of the second transparent resin include a silicone resin, an epoxy resin, and an acrylic resin. The second transparent member 6 has a lower refractive index than the first transparent member 5. The second transparent member 6 may have a refractive index of, for example, about 1.33 to 1.50 inclusive.

The second transparent member 6 may include a body made of the second transparent resin and multiple light scattering particles dispersed in the body. The light scattering particles may have a higher refractive index than the body of the second transparent member 6. The light scattering particles may be made of, for example, silicon oxide (SiO₂). The light scattering particles scatter light received from outside. The light scattering particles reduce the likelihood that light enters the second transparent member 6 from outside and interferes with light emitted from each light emitter 4. The display device 1 can thus avoid lowering the image quality.

In the example of FIG. 2A, the upper surface of the first transparent member 5 (the surface adjacent to the second transparent member 6) is substantially parallel to the third surface 3b, and the lower surface of the second transparent member 6 (the surface adjacent to the first transparent member 5) is substantially parallel to the third surface 3b. In some embodiments, the upper surface of the first transparent member 5 may be curved concavely toward the first plate 2. The lower surface of the second transparent member 6 may be convexly curved toward the first plate 2. The first transparent member 5 and the second transparent member 6 with such shapes form an interface between them with the optical capability of concentrating light emitted from each light emitter 4 on an imaginary line passing through the center of the light emitter 4 and perpendicular to the first surface 2a. The display device 1 thus emits image light with increased directivity.

In the display device 1 according to the present embodiment, the first transparent member 5 is located between the first plate 2 and the second plate 3 and in each through-hole 31. The first transparent member 5 is located on the first surface 2a, between the first surface 2a and the second surface 3a, and in each through-hole 31. This fixes the first plate 2 and the second plate 3 to each other firmly when the display device 1 has higher pixel density, or in other words, when the second plate 3 includes more through-holes 31 with a smaller second surface 3a (the surface facing the first plate 2). In the present embodiment, the display device 1 thus has high definition and high reliability.

In the display device 1 according to the present embodiment, the second transparent member 6 has a lower refractive index than the first transparent member 5. This reduces the likelihood that light emitted from each light emitter 4 cannot travel outside due to total internal reflection at the interface between the first transparent member 5 and the second transparent member 6. This increases the light output efficiency.

The second transparent member 6, which is thicker than the first transparent member 5, may have a higher light transmittance than the first transparent member 5. This greatly increases the total light transmittance of the first transparent member 5 and the second transparent member 6 and allows efficient output of light radiated from each light emitter 4 outside. The second transparent member 6 may have, but is not limited to, a light transmittance greater than and up to about twice the light transmittance of the first transparent member 5.

The surface of the first transparent member 5 adjacent to the second transparent member 6 may be a concave surface (first concave surface) curved toward the light emitter 4. The upper surface of the second transparent member 6 may be a concave surface (second concave surface) curved toward the light emitter 4. The second concave surface may have a smaller curvature than the first concave surface. This avoids lowering the degree of convergence of light radiated outside through each through-hole 31. This structure also increases the contact area (joint area) between the first transparent member 5 and the second transparent member 6, thus joining these members more securely.

Display devices according to variations of the embodiment of the present disclosure will now be described.

As illustrated in, for example, FIG. 3, the display device 1 may include the wavelength converters 7 each between the first transparent member 5 and the second transparent member 6. Each wavelength converter 7 converts light emitted from the light emitter 4 to light with a different wavelength. For the light emitters 4 being blue LEDs, the wavelength converters 7 may convert blue light emitted from the light emitters 4 to red or green light. For the light emitters 4 being ultraviolet LEDs, the wavelength converters 7 may convert ultraviolet light emitted from the light emitters 4 to red, green, or blue light.

Each wavelength converter 7 may contain a phosphor or quantum dots. Each wavelength converter 7 may include a body made of a light-transmissive insulating resin or light-transmissive glass, and phosphor particles or quantum dots dispersed in the body. The phosphor particles or quantum dots may be uniformly dispersed in the body.

The insulating resin used for the wavelength converters 7 may be, for example, an ultraviolet curable resin or a thermosetting resin. Examples of the insulating resin used for the wavelength converters 7 include a fluorinated resin, a silicone resin, an acrylic resin, an epoxy resin, and a urea resin. Examples of the glass used for the wavelength converters 7 include borosilicate glass, crystallized glass, quartz, and soda glass.

Various materials that are excited by light emitted from the light emitters 4 and emit light with wavelengths different from those of the emitted light may be used for the phosphors in the wavelength converters 7. Examples of the phosphor for red fluorescence include La₂O₂S:Eu and Y₂O₂S:Eu. Examples of the phosphor for green fluorescence include ZnS:Cu, Al and SrGa₂S₄:Eu. Examples of the phosphor for blue fluorescence include BaMgAl₁₀O₁₂:Eu and (Sr, Ca, Ba, Mg)₁₀(PO₄)₆Cl₂:Eu. The symbol: Eu refers to Eu being contained as a trace component. Quantum dots are particles with diameters of about 1 to 100 nm inclusive. Examples of the materials used for the quantum dots in the wavelength converters 7 include cadmium selenide (CdSe), cadmium sulfide (CdS), and indium phosphide (InP). The wavelength converters 7 containing quantum dots can emit light with improved color purity.

As illustrated in, for example, FIG. 4, the display device 1 may include color filters 8 each between the second transparent member 6 and the wavelength converter 7. The color filters 8 are made of a resin containing a pigment or a dye. The pigment used for the color filters 8 may be an organic pigment or an inorganic pigment. The resin used for the color filters 8 may be, for example, an ultraviolet curable resin or a thermosetting resin. Examples of the resin used for the color filters 8 include an acrylic resin and a polycarbonate resin.

For the wavelength converters 7 converting blue light from the light emitters 4 to red light, the color filters 8 transmit red light while absorbing visible light other than red light to reduce transmission. In other words, the color filters 8 absorb visible light that is not converted to red light after being emitted from the light emitters 4. The color filters 8 may absorb visible light other than red light to reduce transmission to a level not visually sensible by a viewer. This reduces color mixture with light other than red light and improves the color reproducibility of the display device 1. For the wavelength converters 7 converting blue light from the light emitters 4 to green light, the color filters 8 transmit green light while absorbing visible light other than green light to reduce transmission. In other words, the color filters 8 absorb visible light that is not converted to green light after being emitted from the light emitters 4. This reduces color mixture with light other than green light and improves the color reproducibility of the display device 1.

For the wavelength converters 7 converting ultraviolet light from the light emitters 4 to visible light such as red, green, or blue light, the display device 1 may eliminate the color filters 8. Light that is not converted to visible light by the wavelength converters 7 after being emitted from the light emitters 4 is ultraviolet or near-ultraviolet light, which is substantially invisible to human eyes. Thus, without the color filters 8, the display device 1 undergoes no substantial deterioration of the color reproducibility.

Each wavelength converter 7 may be included in either or both the first transparent member 5 and the second transparent member 6. For the wavelength converter 7 included in the first transparent member 5, the wavelength converter 7 directly converts the wavelength of light emitted from the light emitter 4. This facilitates more efficient wavelength conversion. For the wavelength converter 7 included in the second transparent member 6, the wavelength converter 7 converts the wavelength of light emitted from the light emitter 4 with a long optical path. This facilitates more efficient wavelength conversion.

In the display device 1, each light emitter 4 may emit light to be reflected on the inner peripheral surface 31a of the through-hole 31 at least once. This allows substantially collimated image light to be emitted from the third surface 3b. The display device 1 thus emits image light with increased directivity.

To allow light emitted from each light emitter 4 to be reflected on the inner peripheral surface 31a at least once, the second plate 3 may be, for example thicker than the first plate 2. In other words, each through-hole 31 may be deeper. To allow light emitted from each light emitter 4 to be reflected on the inner peripheral surface 31a of the through-hole 31 at least once, the display device 1 may have parameters determined as appropriate based on, for example, the intensity distribution of light emitted from the light emitter 4. The parameters may include the thickness of the second plate 3, the shape of the through-hole 31, and the dimensional ratio between the through-hole 31 and the light emitter 4.

Each through-hole 31 may have a depth at which at least part of light emitted from the light emitter 4 to be reflected multiple times on the inner peripheral surface 31a. This facilitates radiation of light from the light emitters 4 outside the second plate 3 with a high degree of convergence. Each through-hole 31 may have, but is not limited to, a depth about 3 to 10 times or about 5 to 10 times the height of each light emitter 4.

Each light emitter 4 may emit light with the maximum intensity at an angle to a perpendicular to the upper surface of the light emitter 4. The light emitter 4 may emit light with the maximum intensity to be reflected multiple times on the inner peripheral surface 31a of the through-hole 31. This facilitates efficient radiation of light from the light emitter 4 outside the second plate 3 with a high degree of convergence. Light with the maximum intensity may be reflected about two to five times inclusive or another number of times. The radiation direction of light with the maximum intensity may be at an angle to a perpendicular to the surface of the element-mounting portion 2aa for the light emitter 4. This increases the directivity of light radiated outside through the through-hole 31. To allow light with the maximum intensity to be reflected multiple times on the inner peripheral surface 31a of the through-hole 31, the first plate 2 may have a thickness of, for example, about 0.2 to 2.0 mm, and the second plate 3 may have a thickness of about 1.0 to 3.0 mm. However, the thicknesses are not limited to these values. The direction of light with the maximum intensity may be, but not limited to, at an angle of about 30 to 60° to a perpendicular to the element-mounting portion 2aa.

The through-holes 31 in the second plate 3 may include mirror-like inner peripheral surfaces 31a. This allows light emitted from the light emitters 4 to be reflected on the inner peripheral surfaces 31a with an increased reflectance and a reduced loss. The display device thus outputs light emitted from the light emitters 4 outside more efficiently and displays high-luminance images.

The inner peripheral surfaces 31a of the through-holes 31 may undergo, for example, electrolytic polishing or chemical polishing to have a mirror finish. The inner peripheral surfaces 31a of the through-holes 31 may have a surface roughness Ra of, for example, about 0.01 to 0.1 μm inclusive. The inner peripheral surfaces 31a may have a reflectance of visible light of, for example, about 85 to 95% inclusive.

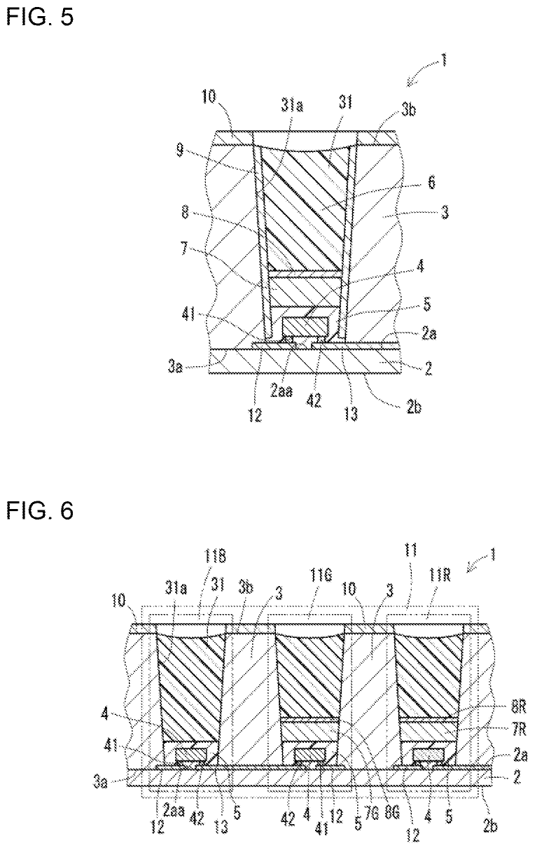

As illustrated in, for example, FIG. 5, the display device 1 may include a light reflective film 9 on the inner peripheral surfaces 31a of the through-holes 31. This allows light emitted from the light emitters 4 to be reflected in the through-holes 31 with an increased reflectance and a reduced loss independently of, for example, the material for the second plate 3 or the surface roughness Ra of the inner peripheral surfaces 31a. The display device 1 thus outputs light emitted from the light emitters 4 outside more efficiently and displays high-luminance images.

The light reflective film 9 may be made of, for example, a metal material. Examples of the metal material used for the light reflective film 9 include aluminum, silver, and gold.

The light reflective film 9 may be formed on the inner peripheral surfaces 31a of the through-holes 31 using a thin film formation method such as CVD, vapor deposition, or plating, or using a thick film formation method such as firing and solidifying a resin paste containing particles of, for example, aluminum, silver, or gold. The light reflective film 9 may be formed on the inner peripheral surfaces 31a of the through-holes 31 by joining a film containing, for example, aluminum, silver, gold, or an alloy of any of these metals. A protective film may be located on the outer surface of the light reflective film 9 to reduce oxidation of the light reflective film 9, which may cause a decrease in reflectance.

The third surface 3b of the second plate 3 may be roughened by, for example, blasting. The roughened third surface 3b has a larger surface area. The second plate 3 with the roughened third surface 3b thus effectively dissipates heat generated by the light emitters 4 and transferred to the second plate 3.

The roughened third surface 3b also diffusely reflects light received from outside (external light). The display device 1 thus emits image light with less interference with reflected external light, avoiding lowering the image quality.

As illustrated in, for example, FIG. 5, the display device 1 may include a light absorbing film 10 on the third surface 3b of the second plate 3. The light absorbing film 10 absorbs external light incident on the third surface 3b. The third surface 3b reduces reflection of external light. The display device 1 thus emits image light with less interference with reflected external light, avoiding lowering the image quality.

The light absorbing film 10 may be formed by, for example, applying a photo-curing or a thermosetting resin material containing a light absorbing material to the third surface 3b of the second plate 3 and curing the material. The light absorbing material may be, for example, an inorganic pigment. Examples of the inorganic pigments include carbon pigments such as carbon black, nitride pigments such as titanium black, and metal oxide pigments such as Cr—Fe—Co, Cu—Co—Mn (manganese), Fe—Co—Mn, and Fe—Co—Ni—Cr pigments.

The light absorbing film 10 may include a rough surface that absorbs incident light. For example, the light absorbing film 10 may be a black film formed by mixing a black pigment such as carbon black in a base material such as a silicone resin and by roughening the surface of the black film. This greatly increases the light absorbing effect. The rough surface may have an arithmetic mean roughness of about 10 to 50 μm or about 20 to 30 μm. The rough surface may be formed by, for example, transferring.

The display device 1 may include multiple pixels 11. As illustrated in, for example, FIG. 6, each pixel 11 may include a subpixel 11R, a subpixel 11G, and a subpixel 11B.

The subpixel 11R may emit red light. The subpixel 11R may include a light emitter 4 that emits blue light and a wavelength converter 7R that converts blue light emitted from the light emitter 4 to red light. As illustrated in, for example, FIG. 6, the wavelength converter 7R may be located on the surface of the first transparent member 5 adjacent to the third surface 3b in the through-hole 31. The subpixel 11R may include a color filter 8R that transmits red light alone. The color filter 8R may be nearer the third surface 3b than the wavelength converter 7R.

The subpixel 11G may emit green light. The subpixel 11G may include a light emitter 4 that emits blue light and a wavelength converter 7G that converts blue light emitted from the light emitter 4 to green light. As illustrated in, for example, FIG. 6, the wavelength converter 7G may be located on the surface of the first transparent member 5 adjacent to the third surface 3b in the through-hole 31. The subpixel 11G may include a color filter 8G that transmits green light alone. The color filter 8G may be nearer the third surface 3b than the wavelength converter 7G.

The subpixel 11B may emit blue light. The subpixel 11G may include a light emitter 4 that emits blue light.

The display device 1 with the above structure can display full colors. The display device 1 with the above structure can display full colors using blue LEDs alone. The display device 1 thus reduces non-uniformity in display images that may be caused by different types of LEDs having different emission characteristics. The display device 1 also reduces the manufacturing cost.

The display device 1 that can display full colors may have the structure described below.

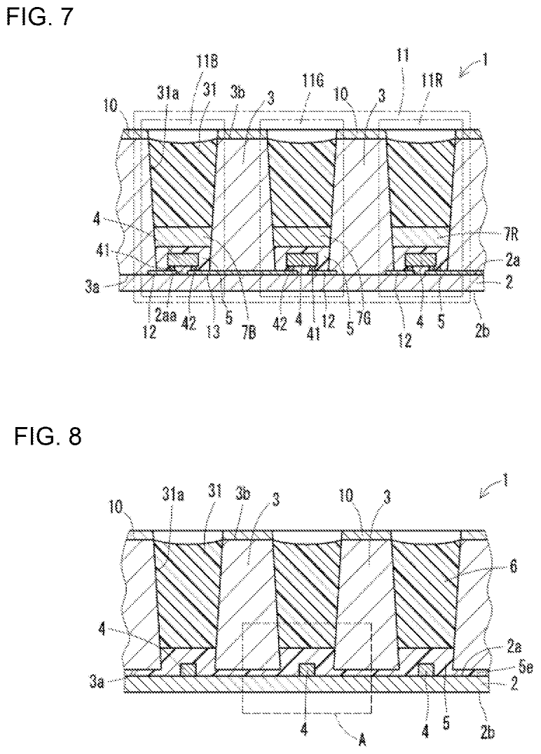

As illustrated in, for example, FIG. 7, the display device 1 includes the subpixel 11R, the subpixel 11G, and the subpixel 11B. The subpixel 11R includes a light emitter 4 that emits ultraviolet light and a wavelength converter 7R that converts ultraviolet light emitted from the light emitter 4 to red light. As illustrated in, for example, FIG. 7, the wavelength converter 7R is located on the surface of the first transparent member 5 adjacent to the third surface 3b in the through-hole 31. The subpixel 11G includes a light emitter 4 that emits ultraviolet light and a wavelength converter 7G that converts ultraviolet light emitted from the light emitter 4 to green light. As illustrated in, for example, FIG. 7, the wavelength converter 7G is located on the surface of the first transparent member 5 adjacent to the third surface 3b in the through-hole 31. The subpixel 11B includes a light emitter 4 that emits ultraviolet light and a wavelength converter 7B that converts ultraviolet light emitted from the light emitter 4 to blue light. As illustrated in, for example, FIG. 7, the wavelength converter 7B is located on the surface of the first transparent member 5 adjacent to the third surface 3b in the through-hole 31.

The display device 1 with the above structure can display full colors without the color filters 8. The display device 1 with the above structure can display full colors using ultraviolet LEDs alone. The display device 1 thus reduces non-uniformity in display images that may be caused by different types of LEDs having different emission characteristics. The display device 1 also reduces the manufacturing cost.

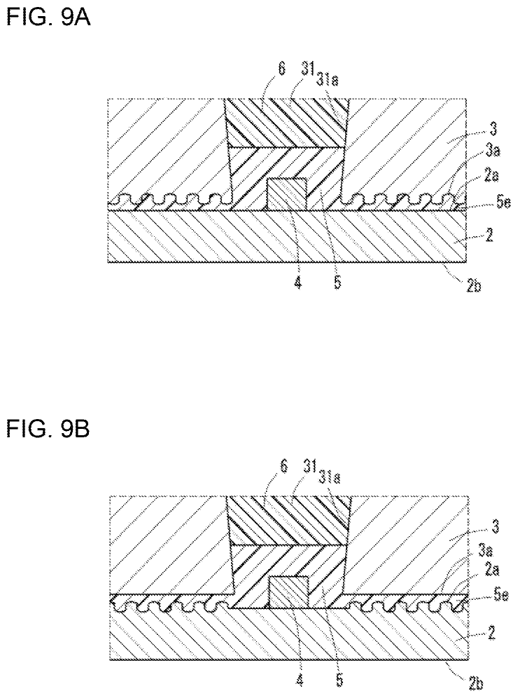

FIG. 8 is a schematic cross-sectional view of a display device according to a variation of the display device in FIG. 2A. FIGS. 9A, 9B, 10A to 10D, and 11A to 11D are each a schematic cross-sectional view of a display device according to a variation of the display device in FIG. 8. FIGS. 9A, 9B, 10A to 10D, and 11A to 11D are each an enlarged view of area A in FIG. 8. FIGS. 8, 9A, 9B, 10A to 10D, and 11A to 11D do not illustrate the anode terminals 41, the cathode terminals 42, the anode electrodes 12, or the cathode electrodes 13.

In the display device 1 in FIG. 8, the second plate 3 is spaced away from the first plate 2 with the first transparent member 5 extending between the first plate 2 and the second plate 3. The first transparent member 5 includes an extension 5e that is thinner than the portion of the first transparent member 5 located in each through-hole 31. The light absorbing film 10 is located on the third surface 3b of the second plate 3. In this case, the extension 5e of the first transparent member 5 joins and fixes the first plate 2 and the second plate 3 firmly. This also reduces the likelihood that light radiated from the light emitters 4 enters the adjacent through-holes 31.

The structure in FIG. 9A is different from the structure in FIG. 8 in that the second surface 3a of the second plate 3 facing the first plate 2 is a rough surface with multiple fine protrusions and recesses. In this case, the extension 5e of the first transparent member 5 has a larger joint area, and thus joins and fixes the first plate 2 and the second plate 3 more firmly. When light radiated from the light emitter 4 enters the extension 5e, the fine protrusions and recesses on the second surface 3a scatter the light and more effectively reduce entry of light into the adjacent through-holes 31. The structure in FIG. 9B is different from the structure in FIG. 8 in that the first surface 2a of the first plate 2 facing the second plate 3 is a rough surface with multiple fine protrusions and recesses. This structure has the same or similar effects as the structure illustrated in FIG. 9A.

For the second plate 3 including the rough second surface 3a, the second surface 3a may have an arithmetic mean roughness of about, but is not limited to, 50 to 1000 nm or about 100 to 1000 nm. The same applies to the first plate 2 including the rough first surface 2a.

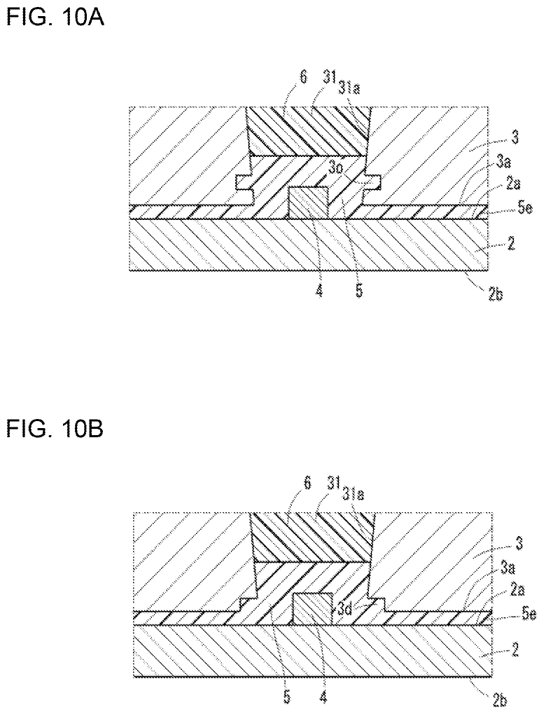

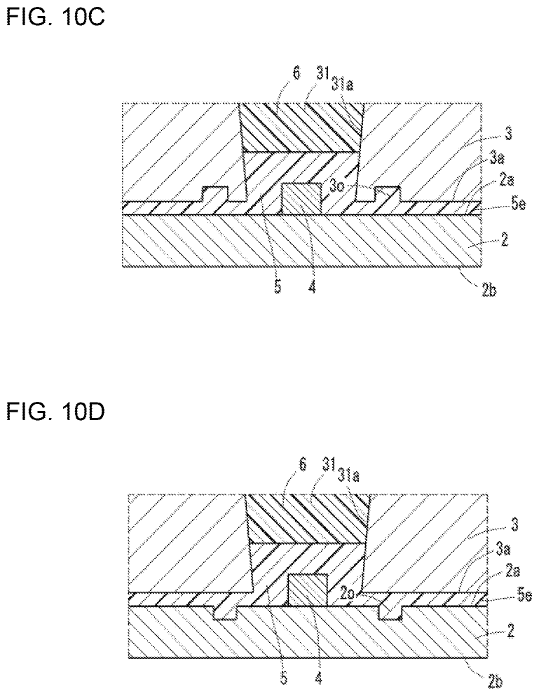

The structure in FIG. 10A is different from the structure in FIG. 8 in that each through-hole 31 in the second plate 3 includes an inner peripheral surface 3h with a recess 3o on its lower end portion in contact with the first transparent member 5. In this case, the first transparent member 5 has a larger joint area, and thus joins and fixes the first plate 2 and the second plate 3 more firmly. The inner peripheral surface 3h may include multiple recesses 3o located in either or both the circumferential direction and the depth direction. The recess 3o may be a groove extending along the entire inner peripheral surface 3h in the circumferential direction. In these cases, the first transparent member 5 has a larger joint area, and thus joins and fixes the first plate 2 and the second plate 3 more firmly.

The structure in FIG. 10B is different from the structure in FIG. 8 in that each through-hole 31 in the second plate 3 includes a step 3d at the lower end corner of the through-hole 31. In this case, the first transparent member 5 has a larger joint area, and thus joins and fixes the first plate 2 and the second plate 3 more firmly. Each step 3d may extend along the entire inner peripheral surface 3h in the circumferential direction. In this case, the first transparent member 5 has a larger joint area, and thus joins and fixes the first plate 2 and the second plate 3 more firmly.

The structure in FIG. 10C is different from the structure in FIG. 8 in that the second plate 3 includes a recess 3o on the second surface 3a. In this case, the first transparent member 5 has a larger joint area, and thus joins and fixes the first plate 2 and the second plate 3 more firmly. When light radiated from the light emitter 4 enters the extension 5e, the recess 3o on the second surface 3a scatters the light and more effectively reduces entry of light into the adjacent through-holes 31. The second surface 3a may include multiple recesses 3o surrounding the light emitters 4 as viewed in plan. The recess 3o may be a groove. In these cases, the first transparent member 5 has a larger joint area, and thus joins and fixes the first plate 2 and the second plate 3 more firmly. When light radiated from the light emitter 4 enters the extension 5e, the recess 3o on the second surface 3a more effectively scatters the light and reduces entry of light into the adjacent through-holes 31. The recess 3o may be located in an edge portion near the light emitter 4 on the second surface 3a. When light radiated from the light emitter 4 enters the extension 5e, the recess 3o near the light emitter 4 scatters the light and more effectively reduces entry of light into the adjacent through-holes 31.

The structure in FIG. 10D is different from the structure in FIG. 8 in that the first plate 2 includes a recess 2o on the first surface 2a. In this case, the first transparent member 5 has a larger joint area, and thus joins and fixes the first plate 2 and the second plate 3 more firmly. When light radiated from the light emitter 4 enters the extension 5e, the recess 2o on the first surface 2a scatters the light and more effectively reduces entry of light into the adjacent through-holes 31. The first surface 2a may include multiple recesses 2o surrounding the light emitters 4 as viewed in plan. The recess 2o may be a groove. In these cases, the first transparent member 5 has a larger joint area, and thus joins and fixes the first plate 2 and the second plate 3 more firmly. When light radiated from the light emitter 4 enters the extension 5e, the recess 2o on the first surface 2a more effectively scatters the light and reduces entry of light into the adjacent through-holes 31. The recess 2o may be located near the light emitter 4 on the first surface 2a. When light radiated from the light emitter 4 enters the extension 5e, the recess 2o near the light emitter 4 scatters the light and more effectively reduces entry of light into the adjacent through-holes 31.

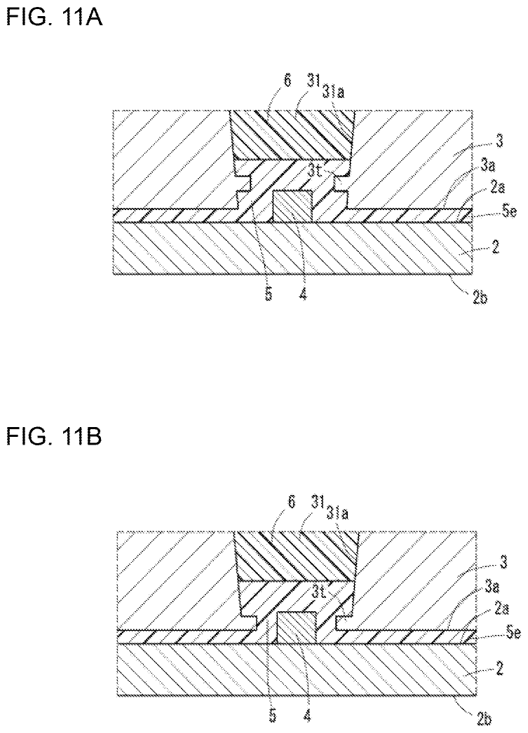

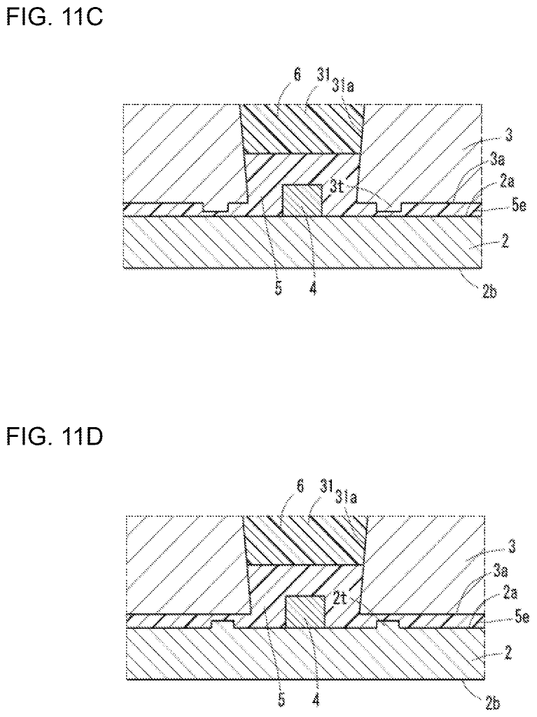

The structure in FIG. 11A is different from the structure in FIG. 8 in that each through-hole 31 in the second plate 3 includes an inner peripheral surface 3h with a protrusion 3t on its lower end portion in contact with the first transparent member 5. In this case, the first transparent member 5 has a larger joint area, and thus joins and fixes the first plate 2 and the second plate 3 more firmly. The inner peripheral surface 3h may include multiple protrusions 3t located in either or both the circumferential direction and the depth direction. The protrusion 3t may be a bank extending along the entire inner peripheral surface 3h in the circumferential direction. In these cases, the first transparent member 5 has a larger joint area, and thus joins and fixes the first plate 2 and the second plate 3 more firmly.

The structure in FIG. 11B is different from the structure in FIG. 8 in that each through-hole 31 in the second plate 3 includes a protrusion 3t at the lower end corner of the through-hole 31. In this case, the first transparent member 5 has a larger joint area, and thus joins and fixes the first plate 2 and the second plate 3 more firmly. The protrusion 3t may extend as a bank along the entire inner peripheral surface 3h in the circumferential direction. In this case, the first transparent member 5 has a larger joint area, and thus joins and fixes the first plate 2 and the second plate 3 more firmly.

The structure in FIG. 11C is different from the structure in FIG. 8 in that the second plate 3 includes a protrusion 3t on the second surface 3a. In this case, the first transparent member 5 has a larger joint area, and thus joins and fixes the first plate 2 and the second plate 3 more firmly. When light radiated from the light emitter 4 enters the extension 5e, the protrusion 3t on the second surface 3a scatters the light and more effectively reduces entry of light into the adjacent through-holes 31. The second surface 3a may include multiple protrusions 3t surrounding the light emitters 4 as viewed in plan. The protrusion 3t may be a bank. In these cases, the first transparent member 5 has a larger joint area, and thus joins and fixes the first plate 2 and the second plate 3 more firmly. When light radiated from the light emitter 4 enters the extension 5e, the protrusion 3t on the second surface 3a more effectively scatters the light and reduces entry of light into the adjacent through-holes 31. The protrusion 3t may be located in an edge portion near the light emitter 4 on the second surface 3a. When light radiated from the light emitter 4 enters the extension 5e, the protrusion 3t near the light emitter 4 scatters the light and more effectively reduces entry of light into the adjacent through-holes 31.

The structure in FIG. 11D is different from the structure in FIG. 8 in that the first plate 2 includes a protrusion 2t on the first surface 2a. In this case, the first transparent member 5 has a larger joint area, and thus joins and fixes the first plate 2 and the second plate 3 more firmly. When light radiated from the light emitter 4 enters the extension 5e, the protrusion 2t on the first surface 2a scatters the light and more effectively reduces entry of light into the adjacent through-holes 31. The first surface 2a may include multiple protrusions 2t surrounding the light emitters 4 as viewed in plan. The protrusion 2t may be a bank. In these cases, the first transparent member 5 has a larger joint area, and thus joins and fixes the first plate 2 and the second plate 3 more firmly. When light radiated from the light emitter 4 enters the extension 5e, the protrusion 2t on the first surface 2a more effectively scatters the light and reduces entry of light into the adjacent through-holes 31. The protrusion 2t may be located near the light emitter 4 on the first surface 2a. When light radiated from the light emitter 4 enters the extension 5e, the protrusion 2t near the light emitter 4 scatters the light and more effectively reduces entry of light into the adjacent through-holes 31.

In one or more embodiments of the present disclosure, the display device 1 may be a transparent display device including the first plate 2 and the second plate 3 each made of a flexible transparent material such as a transparent resin material. In this case, the display device 1 is installable on curved walls or other non-flat walls in, for example, buildings, vehicles, aircraft, or ships. The display device 1 may also be a flexible double-sided transparent display device. In this case, the display device 1 is installable on glass windows or other transparent members in, for example, buildings, vehicles, aircraft, or ships, and can display images on the front side and the back side. The front side and the back side may display the same or different images.

In one or more embodiments of the present disclosure, a method for manufacturing the display device 1 includes first preparation, second preparation, mounting, application, placement, first formation, filling, and second formation. The first preparation is the process of preparing the first plate 2 including the mounting surface (first surface) 2a. The mounting surface includes portions 2aa on which the light emitters 4 are mountable. The second preparation is the process of preparing the second plate 3 including the through-holes 31. The mounting is the process of mounting the light emitters 4 on the portions 2aa of the first plate 2. Each light emitter 4 includes an upper surface, a side surface, and a lower surface. The application is the process of applying the first transparent resin to the mounting surface 2a and to at least the side surfaces of the light emitters 4. The placement is the process of placing the second plate 3 on the mounting surface 2a of the first plate 2 to position the light emitters 4 in the through-holes 31. The first formation is the process of curing the first transparent resin to form the first transparent member 5 in the through-holes 31 and between the first plate 2 and the second plate 3. The first transparent member 5 fixes the first plate 2 and the second plate 3 to each other and seals the light emitters 4. The filling is the process of filling the through-holes 31 with the second transparent resin having a lower refractive index than the first transparent resin. The second formation is the process of curing the second transparent resin to form the second transparent member 6 thicker than the first transparent member 5. The display device 1 manufactured with this method has high reliability, high light output efficiency, and high definition.

The placement may include pressing the first plate 2 and the second plate 3 relative to each other. In this case, simply adjusting the pressing force allows the extension 5e of the first transparent member 5 to be thinner than the portion of the first transparent member 5 located in each through-hole 31 as in the structure in FIG. 8. The extension 5e of the first transparent member 5 may be eliminated by increasing the pressing force. For the pressing operation, the second plate 3 may be placed in a manner movable relative to the first plate 2 fixed on a fixture such as a table, and the second plate 3 may be pressed against the fixed first plate 2. In some embodiments, the first plate 2 may be placed in a manner movable relative to the second plate 3 suspended with, for example, a suspension device, and the first plate 2 may be pressed against the fixed second plate 3. The first plate 2 and the second plate 3 may both be placed in a manner movable relative to each other and pressed against each other.

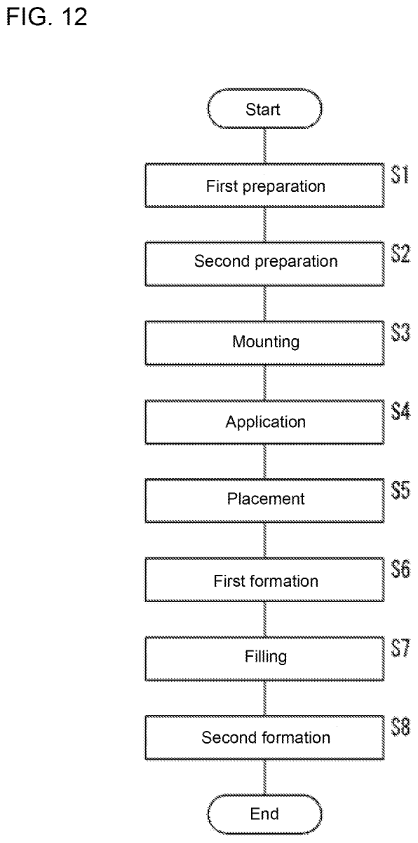

A method for manufacturing the display device according to an embodiment of the present disclosure will now be described. FIG. 12 is a flowchart of a method for manufacturing the display device according to the embodiment of the present disclosure.

In the present embodiment, the method for manufacturing the display device includes first preparation S1, second preparation S2, mounting S3, application S4, placement S5, first formation S6, filling S7, and second formation S8.

The first preparation S1 is the process of preparing the first plate 2. The first plate 2 may be produced using, for example, the glass material, the ceramic material, the resin material, the metal material, or the semiconductor material described above. In this process, the anode electrodes 12 and the cathode electrodes 13 may be formed on the portions (element-mounting portions) 2aa of the first surface 2a of the first plate 2 on which the light emitters 4 are mountable. In this process, components for driving the light emitters 4 such as electrodes, wiring conductors, or drive circuits may be formed on at least one of the first main surface 2a or the second main surface 2b of the first plate 2.

The second preparation S2 is the process of preparing the second plate 3. The second plate 3 may be produced using, for example, the glass material, the ceramic material, the resin material, the metal material, or the semiconductor material described above. The through-holes 31 extending through the second plate 3 from the second surface 3a to the third surface 3b may be formed by, for example, punching, electroforming (plating), cutting, laser beam machining, or photolithography including dry etching. In this process, the inner peripheral surfaces 31a of the through-holes 31 may have a mirror finish, or may be coated with a light reflective film. In this process, the third surface 3b of the second plate 3 may be roughened, or may be coated with a light absorbing film.

The first preparation S1 and the second preparation S2 may be performed in an order other than the order in FIG. 12. The first preparation S1 may be performed after the second preparation S2 is performed, or the first preparation S1 and the second preparation S2 may be performed simultaneously.

The mounting S3 is the process of mounting the light emitters 4 on the portions 2aa of the first plate 2. In this process, the light emitters 4 may be connected to the anode electrodes 12 and the cathode electrodes 13 on the element-mounting portions 2aa by flip-chip connection.

The application S4 is the process of applying the first transparent resin to the first surface 2a of the first plate 2 and to the light emitters 4 mounted on the element-mounting portions 2aa. The first transparent resin may be applied using, for example, a dispenser or a slot-die coater.

The placement S5 is the process of positioning the first plate 2 and the second plate 3 relative to each other. In this process, the first plate 2 and the second plate 3 are positioned relative to each other to cause the first surface 2a and the second surface 3a to face each other and to cause the light emitters 4 to be located in the through-holes 31. Each light emitter 4 may be at least partially located in the corresponding through-hole 31.

The first formation S6 is the process of curing the first transparent resin to form the first transparent member 5. The first transparent member 5 fixes the first plate 2 and the second plate 3 to each other and seals each light emitter 4. The first transparent resin may be cured by, for example, using ultraviolet light or heat or by mixing two components in accordance with the polymerization characteristics or the curing characteristics of the resin.

The filling S7 is the process of filling the through-holes 31 with the second transparent resin having a lower refractive index than the first transparent resin. In this process, the second transparent resin is discharged using, for example, a dispenser or a slot-die coater onto the first transparent member 5 in each through-hole 31 from a position adjacent to the third surface 3b of the second plate 3. In this process, the second transparent resin may be placed on the first transparent member 5 to the height of the third surface 3b, or to a height between the third surface 3b and the surface of the first transparent member 5 adjacent to the third surface 3b.

The second formation S8 is the process of curing the second transparent resin placed on the first transparent member 5 to form the second transparent member 6. The second transparent resin may be cured by, for example, using ultraviolet light or heat or by mixing two components in accordance with the polymerization characteristics or the curing characteristics of the resin.

With the above method, the display device 1 illustrated in, for example, FIGS. 1, 2A, and 2B can be manufactured.

The method for manufacturing the display device may include wavelength converter formation between the first formation S6 and the filling S7.

The wavelength converter formation is the process of forming each wavelength converter 7 on the surface of the first transparent member 5 adjacent to the third surface 3b. In this process, an insulating resin containing dispersed phosphor particles or quantum dots is discharged using, for example, an inkjet printer or a dispenser onto the first transparent member 5 in each through-hole 31 from a position adjacent to the third surface 3b of the second plate 3. The insulating resin may be an ultraviolet curable resin or a thermosetting resin. The insulating resin placed on the first transparent member 5 is cured by, for example, using ultraviolet light or heat in accordance with the polymerization characteristics or the curing characteristics of the resin. In this manner, the wavelength converters 7 can be formed.

The method for manufacturing the display device may include color filter formation after the wavelength converter formation before the filling S7. The color filter formation is the process of forming the color filters 8 on the surfaces of the wavelength converters 7 adjacent to the third surface 3b. In this process, a resin containing a pigment or a dye is discharged using, for example, an inkjet printer or a dispenser onto the wavelength converters 7 in the through-holes 31 from a position adjacent to the third surface 3b of the second plate 3. The resin may be an ultraviolet curable resin or a thermosetting resin. The resin placed on the wavelength converters 7 is cured by, for example, using ultraviolet light or heat in accordance with the polymerization characteristics or the curing characteristics of the resin. In this manner, the color filters 8 can be formed.

As described above, in one or more embodiments of the present disclosure, the display device includes the second transparent member on the first transparent member in the through-hole in the second substrate. The second transparent member has a lower refractive index and a greater thickness than the first transparent member. This allows efficient output of light radiated from the light emitter outside. This increases the directivity of light radiated outside through the through-hole. The first transparent member and the second transparent member hermetically seal the light emitter and efficiently transfer heat from the light emitter to the second substrate, which then dissipates the heat. This improves the device reliability. Thus, the display device has high reliability, high light output efficiency, and high definition. The manufacturing method according to one or more embodiments of the present disclosure provides the display device with high reliability, high light output efficiency, and high definition.

Although the embodiments of the present disclosure have been described in detail, the present disclosure is not limited to the embodiments described above, and may be changed or varied in various manners without departing from the spirit and scope of the present disclosure. The components described in the above embodiments may be entirely or partially combined as appropriate unless any contradiction arises.

### INDUSTRIAL APPLICABILITY

The display device according to one or more embodiments of the present disclosure can be used in various electronic devices. Such electronic devices include automobile route guidance systems (car navigation systems), ship route guidance systems, aircraft route guidance systems, indicators for instruments in vehicles such as automobiles, instrument panels, smartphones, mobile phones, tablets, personal digital assistants (PDAs), video cameras, digital still cameras, electronic organizers, electronic books, electronic dictionaries, personal computers, copiers, terminals for game devices, television sets, product display tags, price display tags, programmable display devices for industrial use, car audio systems, digital audio players, facsimile machines, printers, automatic teller machines (ATMs), vending machines, medical display devices, digital display watches, smartwatches, guidance display devices installed in stations or airports, and signage (digital signage) for advertisement.

### REFERENCE SIGNS

1 display device
2 first substrate (first plate)
2a first surface (first main surface or mounting surface)
2aa portion (element-mounting portion)
2b second main surface
2o recess
2t protrusion
3 second substrate (second plate)
3a second surface
3b third surface
3h inner peripheral surface
3o recess
3t protrusion
31 through-hole
31a inner peripheral surface
31b opening
4 light emitter
41 anode terminal
42 cathode terminal
5 first transparent member
5e extension
6 second transparent member
7, 7R, 7G, 7B wavelength converter
8, 8R, 8G color filter
9 light reflective film
10 light absorbing film
11 pixel
11R, 11G, 11B subpixel
12 anode electrode
13 cathode electrode

1. A display device comprising:
a first substrate;
a second substrate on the first substrate, the second substrate including a through-hole extending through the second substrate in a direction in which the second substrate is placed on the first substrate;
a light emitter mounted on a portion of the first substrate exposed by the through-hole, the light emitter including an upper surface and a side surface;
a first transparent member in the through-hole, the first transparent member sealing at least the side surface of the light emitter; and
a second transparent member on the first transparent member in the through-hole, the second transparent member having a lower refractive index and a greater thickness than the first transparent member.

2. The display device according to claim 1, wherein
the first transparent member comprises a transparent resin adhesive.

3. The display device according to claim 1, wherein
the light emitter is sealed hermetically by the first transparent member and the second transparent member in the through-hole.

4. The display device according to claim 1, wherein
the second substrate is spaced away from the first substrate, and
the first transparent member extends between the first substrate and the second substrate.

5. The display device according to claim 4, wherein
the first transparent member includes an extension extending between the first substrate and the second substrate, and the extension is thinner than a portion of the first transparent member located in the through-hole.

6. The display device according to claim 4, wherein
the second substrate includes a rough surface facing the first substrate.

7. The display device according to claim 4, wherein
the first substrate includes a rough surface facing the second substrate.

8. The display device according to claim 1, further comprising:
a wavelength converter between the first transparent member and the second transparent member.

9. The display device according to claim 8, wherein
the wavelength converter contains a phosphor or quantum dots.

10. The display device according to claim 8, further comprising:
a color filter between the wavelength converter and the second transparent member.

11. The display device according to claim 8, wherein
the upper surface of the light emitter is exposed through the first transparent member.

12. The display device according to claim 1, wherein
the through-hole has a depth at which at least part of light emitted from the light emitter to be reflected a plurality of times on an inner peripheral surface of the through-hole.

13. The display device according to claim 12, wherein
the light emitter emits light with a maximum intensity at an angle to a perpendicular to the upper surface of the light emitter, and
the light emitter emits the light with the maximum intensity to be reflected a plurality of times on the inner peripheral surface of the through-hole.

14. The display device according to claim 1, further comprising:
a light reflective film on an inner peripheral surface of the through-hole.

15. The display device according to claim 1, wherein
the second substrate includes a display surface opposite to the first substrate, and
the display device further comprises a light absorbing film on the display surface.

16. A method for manufacturing a display device, the method comprising:
preparing a first substrate including a mounting surface, the mounting surface including a portion on which a light emitter is mountable;
preparing a second substrate including a through-hole;
mounting a light emitter on the portion of the first substrate, the light emitter including an upper surface and a side surface;
applying a first transparent resin to the mounting surface and to at least the side surface of the light emitter;
placing the second substrate on the mounting surface of the first substrate to position the light emitter in the through-hole;
curing the first transparent resin to form a first transparent member in the through-hole and between the first substrate and the second substrate, the first transparent member fixing the first substrate and the second substrate to each other and sealing the light emitter;
filling the through-hole with a second transparent resin, the second transparent resin having a lower refractive index than the first transparent resin; and
curing the second transparent resin to form a second transparent member thicker than the first transparent member.

17. The method according to claim 16, wherein
placing the second substrate includes pressing the first substrate and the second substrate relative to each other.
